(19) United States
(12) Patent Application Publication
(10) Pub. No.: US 2025/0218773 A1
(43) Pub. Date: Jul. 3, 2025

(54) AMORPHOUS CARBON FILM AND DEPOSITION METHOD THEREOF

(71) Applicant: TES Co., Ltd, Yongin-si (KR)

(72) Inventors: Seung Hwan JEON, Yongin-si (KR); Hye Ok KIM, Yongin-si (KR); Sungho KIM, Yongin-si (KR)

(73) Assignee: TES Co., Ltd, Yongin-si (KR)

(21) Appl. No.: 19/002,154

(22) Filed: Dec. 26, 2024

(30) Foreign Application Priority Data
Dec. 27, 2023 (KR) 10-2023-0193360

(51) Int. Cl. H01L 21/033; C23C 16/26; C23C 16/46; C23C 16/50

(52) U.S. Cl. CPC H01L 21/0332; C23C 16/26; C23C 16/46; C23C 16/50

(57) ABSTRACT

Disclosed are an amorphous carbon film having excellent film quality such as hardness, modulus, density, and the like, and a deposition method thereof. The method for depositing the amorphous carbon film includes (a) loading a substrate into a chamber; (b) supplying a carbon precursor and a nitrogen gas into the chamber; (c) raising a temperature of the substrate to 350 to 450° C.; and (d) discharging the carbon precursor and the nitrogen gas in the chamber to deposit a nitrogen-doped amorphous carbon film on the substrate, wherein a flow rate of the nitrogen gas is in a range of about 1500 to 4000 sccm during the step (d).

### CROSS-REFERENCE TO RELATED APPLICATION

This application claims priority from Korean Patent Application No. 10-2023-0193360 filed on Dec. 27, 2023, in the Korean Intellectual Property Office, and all the benefits accruing therefrom under 35 U.S.C. 119, the contents of which in its entirety are herein incorporated by reference.

### BACKGROUND

The present disclosure relates to a deposition technique of an amorphous carbon film mainly used as a hard mask in a semiconductor manufacturing process. More specifically, the present disclosure relates to a method for depositing an amorphous carbon film capable of exhibiting excellent film characteristics through control of a process gas and RF power.

In addition, the present disclosure relates to an amorphous carbon film having excellent hardness, modulus, density, and the like, and having non-excessive stress and bow values.

A NAND apparatus structure that is recently applied in a semiconductor manufacturing process includes a horizontal NAND structure and a vertical NAND structure. As a finer pattern is required, a lot of research on the vertical NAND structure has recently been conducted.

In order to achieve the vertical NAND structure, a hard mask process requiring high selectivity is required. In order to satisfy this requirement, an amorphous carbon film (ACL) has been used as a representative hard mask. The amorphous carbon film as a hard mask is deposited on a multilayer insulating film in which silicon oxide films and silicon nitride films are alternately stacked on top of each other in several tens to several hundreds of layers in a vertical direction using a plasma enhanced chemical vapor deposition (PECVD) process, and then a narrow and elongate hole vertically extending through the multilayer insulating film is formed through an etching process.

In consideration of the high number of layers of the multilayer insulating film in the vertical NAND apparatus, in order for the amorphous carbon film to function as the hard mask, the etch selectivity of the amorphous carbon film should be high, and the amorphous carbon film should be maintained during the etching process.

In addition, when the amorphous carbon film that is not dense is deposited, a problem in which a rear surface of the wafer is damaged may occur when a high chuck voltage is applied in a subsequent process. In order to solve this problem, it has been proposed to inject carrier gas together while using liquid trimethylbenzene instead of C₃H₆ as a gas source as an amorphous carbon source. In this scheme, amorphous carbon gas is injected using a liquid amorphous carbon film source, and at the same time, a carrier gas is injected to reduce a formation rate of the amorphous carbon film, thereby enhancing the hardness of the film. However, in the case of using the liquid source as described above, a non-rigid film is basically formed. Thus, even when the carrier gas is injected together, there is a limitation in that the hardness improvement effect of the formed amorphous carbon film is not significant.

### SUMMARY

A purpose of the present disclosure is to provide a deposition method of an amorphous carbon film having excellent film characteristics such as hardness, modulus, and density through process gas and RF power control.

In addition, a purpose of the present disclosure is to provide an amorphous carbon film having excellent film characteristics such as hardness, modulus, and density.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In order to achieve the purposes, a first aspect of the present disclosure provides a method for depositing an amorphous carbon film, the method comprising: (a) loading a substrate into a chamber; (b) supplying a carbon precursor and a nitrogen gas into the chamber; (c) raising a temperature of the substrate to 350 to 450° C.; and (d) discharging the carbon precursor and the nitrogen gas in the chamber to deposit a nitrogen-doped amorphous carbon film on the substrate, wherein a flow rate of the nitrogen gas is in a range of about 1500 to 4000 sccm (standard cubic centimeter per minute) during the step (d).

In accordance with some embodiments of the method for depositing the amorphous carbon film, the carbon precursor together with a carrier gas is supplied into the chamber, wherein the carrier gas includes argon gas.

In accordance with some embodiments of the method for depositing the amorphous carbon film, the carrier gas is free of helium gas.

In accordance with some embodiments of the method for depositing the amorphous carbon film, the argon gas is supplied at a flow rate of about 3000 sccm or smaller, more preferably, about 2000 sccm or smaller.

In accordance with some embodiments of the method for depositing the amorphous carbon film, the carbon precursor is a carbon precursor in a gaseous state at room temperature.

In accordance with some embodiments of the method for depositing the amorphous carbon film, the carbon precursor is selected from C₂H₂, C₂H₄, C₂H₆, C₃H₆ and C₃H₈.

In accordance with some embodiments of the method for depositing the amorphous carbon film, in the step (d), a high frequency power of about 1500 W or greater is applied.

In accordance with some embodiments of the method for depositing the amorphous carbon film, in the step (d), both a high frequency power of about 1500 W or greater and a low frequency power of about 1000 W or lower are applied.

In accordance with some embodiments of the method for depositing the amorphous carbon film, the step (d) is performed at a pressure of about 5 to 9 Torr.

In order to achieve the purposes, a second aspect of the present disclosure provides an amorphous carbon film characterized in that nitrogen is doped into a carbon base, and exhibits a hardness of about 5.0 GPa or greater, a modulus of about 36 GPa or greater, and a density of about 1.7 g/cm³ or greater.

In accordance with some embodiments of the amorphous carbon film, the amorphous carbon layer is subjected to the compressive stress of about 220 MPa or lower and exhibits a bow value of about 300 μm or smaller.

According to the method for depositing the amorphous carbon film of the present disclosure, the amorphous carbon film having excellent hardness, modulus, density, and the like and having non-excessive compressive stress and bow value can be deposited via the nitrogen gas (N₂) flow rate control for doping the nitrogen (N), the carrier gas control, the RF power control, and the like while using the low temperature PECVD process of about 400° C.

Accordingly, the deposited nitrogen-doped amorphous carbon layer may have excellent film quality. Thus, for example, even when the number of layers of the NAND flash memory device increases, the deposited nitrogen-doped amorphous carbon layer may be used as a hard mask without significantly increasing the thickness of the amorphous carbon layer.

The effects of the present disclosure are not limited to the above-mentioned effects, and other effects as not mentioned will be clearly understood by those skilled in the art from the following detailed description.

### BRIEF DESCRIPTION OF DRAWINGS

FIG. 1 schematically illustrates an amorphous carbon film deposition method according to the present disclosure.

FIG. 2A schematically illustrates an example of a PECVD apparatus that may be used in a method for depositing an amorphous carbon film according to the present disclosure.

FIG. 2B schematically illustrates another example of a PECVD apparatus that may be used in a method for depositing an amorphous carbon film according to the present disclosure.

FIGS. 3A and 3B show changes in modulus and hardness based on a nitrogen gas flow rate.

FIGS. 4A and 4B show changes in modulus and hardness based on low frequency power.

### REFERENCE NUMERALS

1: PECVD apparatus
2: Chamber
3: Showerhead
4: Susceptor
5, 5a: high frequency power
5b: low frequency power
6: First electrode
7: RF Filter
8: Ground Line

### DETAILED DESCRIPTIONS

Hereinafter, a preferred embodiment of the present disclosure will be described in detail with reference to the accompanying drawings. Advantages and features of the present disclosure, and a method of achieving the advantages and features will become apparent with reference to embodiments described below in detail together with the accompanying drawings. However, the present disclosure is not limited to the embodiments as disclosed below, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expressions such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

Throughout the present disclosure, “A and/or B” means A, B, or A and B, unless otherwise specified, and “C to D” means C inclusive to D inclusive unless otherwise specified.

Hereinafter, an amorphous carbon film deposition method according to a preferred embodiment of the present disclosure will be described in detail with reference to the accompanying drawings.

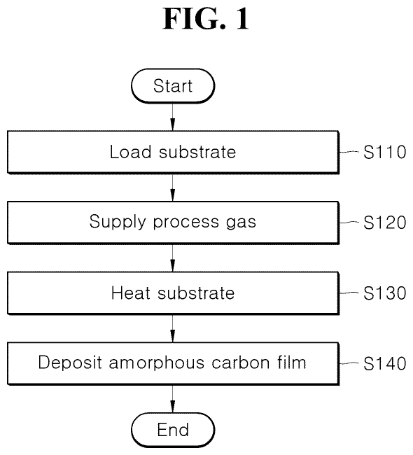

FIG. 1 schematically illustrates an amorphous carbon film deposition method according to the present disclosure.

Referring to FIG. 1, the method of depositing the amorphous carbon film according to the present disclosure includes a substrate loading step S110, a process gas supply step S120, a substrate heating step S130, and an amorphous carbon film deposition step S140. In this regard, the substrate heating step S130 may be started after the process gas supply step S120 has been started. In another example, the process gas supply step S120 and the substrate heating step S130 may be simultaneously started. In still another example, after the substrate heating step S130 has been started, the process gas supply step S120 may be started.

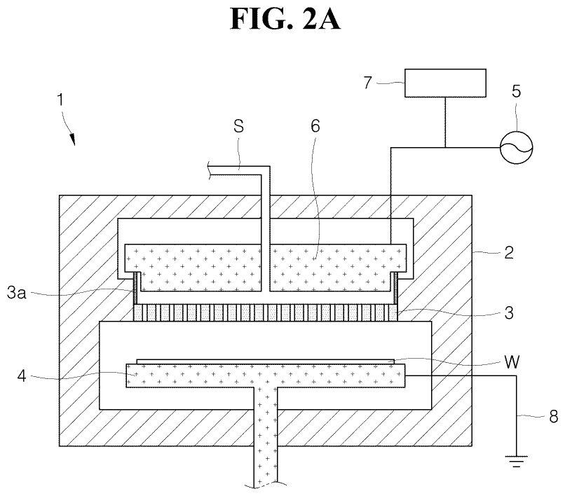

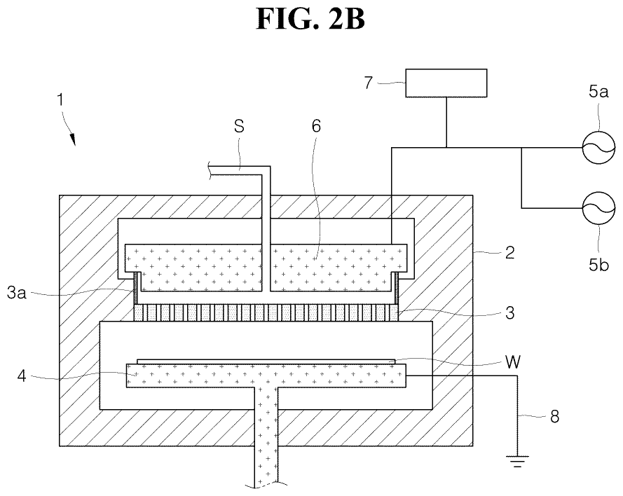

In the substrate loading step S110, the substrate is loaded into the chamber. Specifically, the substrate is loaded on the susceptor (4 in FIGS. 2A and 2B) in the chamber. The substrate on which the amorphous carbon film is to be deposited may be a circular wafer or a quadrangular wafer. A predetermined pattern may be formed on the substrate.

After loading the substrate, an inside of the chamber is evacuated using an external vacuum system (not shown).

Next, in the process gas supply step S120, the carbon precursor and the nitrogen gas are supplied into the chamber.

Next, in the substrate heating step S130, the substrate temperature is raised to about 350 to 450° C., preferably 450° C. In amorphous carbon film deposition, it is known that a dense amorphous carbon film is deposited when the substrate temperature is about 600° C. or higher rather than when the substrate temperature is a low temperature of about 450° C. That is, it is known that the dense amorphous carbon film deposition is not achieved in the low temperature deposition. Thus, in accordance with the present disclosure, film quality such as hardness, modulus, and density may be improved even in the low temperature amorphous carbon film deposition at about 350 to 450° C. through nitrogen gas flow rate control for the nitrogen doping as described below.

Next, in the amorphous carbon film deposition step S140, a nitrogen-doped amorphous carbon film is deposited on the substrate by discharging the carbon precursor and the nitrogen gas in the chamber out of the chamber.

FIG. 2A schematically illustrates an example of a PECVD apparatus that may be used in a method for depositing an amorphous carbon film according to the present disclosure.

Referring to FIG. 2A, the illustrated PECVD apparatus 1 includes a gas supply line S, a chamber 2, a showerhead 3, a susceptor 4, a high frequency power source 5a, a low frequency power source 5b, and a first electrode 6.

The gas supply line S serves to supply a process gas outside the chamber 2 into the chamber 2. In accordance with the present disclosure, the process gas may be a carbon precursor and a nitrogen gas, and may further contain a carrier gas. In FIGS. 2A and 2B, only one gas supply line S connected to the chamber 2 is illustrated.

In this case, a plurality of gas supply lines may be connected to one gas supply line connected to the chamber 2. In another example, each gas supply line may be connected to the chamber 2.

The carbon precursor may be independently supplied into the chamber without the carrier gas or may be supplied into the chamber together with an inert gas as a carrier gas.

In one example, when the carbon precursor is liquid, the liquid carbon precursor may be vaporized through a vaporizer and then may be supplied into the chamber. However, it is more preferable to use a gaseous carbon precursor such as C₃H₆ for the implementation of a dense film.

The inert gas together with the precursor may be supplied into the chamber, or may be supplied into the chamber through a separate gas supply line.

The showerhead 3 is disposed at an upper side of the inner space of the chamber 2 and sprays the process gas injected through the gas supply line S into the chamber.

The susceptor 4 on which the substrate W such as a wafer is loaded (supported) is provided at a lower side of the inner space of the chamber 2. The susceptor 4 may be provided with a temperature control means for raising/cooling the substrate. In addition, the susceptor 4 may function as a ground electrode, as illustrated in FIG. 2A. A separate ground line 8 may be provided to further improve grounding performance. Although not shown, a high frequency power source or an DC power source may be connected to the susceptor 4 itself which thus may act as a second electrode (bias electrode).

The first electrode 6 is electrically connected to the high-frequency power supply 5 and is used as an electrode for plasma discharge in the chamber 2. In the example shown in FIG. 2A, the showerhead 3 is electrically connected to the first electrode 6 by a connector 3a so that the first electrode 6 and the showerhead 3 function as a single electrode together. Accordingly, the RF power generated by the high-frequency power supply 5 is filtered through an RF filter 7 and applied to the inner space of the process chamber 2 through the first electrode 6 and the showerhead 3. In accordance with the present disclosure, a high frequency power of about 1500 W or higher is generated in the high frequency power supply 5. In one example, a high frequency power of about 2000 to 4000 W, more preferably about 2000 to 2500 W is generated therefrom in consideration of the deposition rate.

FIG. 2B schematically illustrates another example of a PECVD apparatus that may be used in a method for depositing an amorphous carbon film according to the present disclosure.

In the apparatus shown in FIG. 2A, only the high frequency power is applied, while in the apparatus shown in FIG. 2B, the low frequency power together with the high frequency power are applied.

Referring to FIG. 2B, the RF power generated by the high frequency power source 5a and RF power generated by the low frequency power source 5b are filtered through the RF filter 7 and applied to the inner space of the process chamber 2 through the first electrode 6 and the showerhead 3. The high frequency power source 5a generates high frequency power of about 1500 W or higher, and the low frequency power source 5b generates low frequency power of about 1000 W or lower. Preferably, the low frequency power source 5b generates a low frequency power in a range of about 100 to 500 W.

The amorphous carbon film deposition method according to the present disclosure may use various known PECVD apparatuses in addition to using the PECVD apparatus as illustrated in each of FIGS. 2A and 2B.

In accordance with the present disclosure, the flow rate of nitrogen is about 1500 sccm (standard cubic centimeter per minute) or greater while the amorphous carbon film deposition step S140 is performed.

The inventors of the present disclosure have found that in doping nitrogen into the amorphous carbon film, nitrogen doping is effectively performed under the nitrogen gas flow rate of at least about 1500 sccm, more preferably at least about 2000 sccm when the amorphous carbon film is deposited, thereby improving properties such as hardness, modulus, density, and the like of the amorphous carbon film.

Nitrogen gas (N₂) is mainly used as a purge gas. When the nitrogen gas is used as a carrier gas or a reaction gas, it is supplied into the chamber at a flow rate of about 500 sccm. In accordance with the present disclosure, nitrogen gas (N₂) is used as a reaction gas for nitrogen doping, and the flow rate thereof is about 1500 sccm or greater, more preferably about 2000 sccm or greater. In addition, the nitrogen source for nitrogen doping is mainly N₂O or NO. However, according to the present disclosure, the nitrogen gas (N₂) is used as a source for nitrogen doping. Since the nitrogen gas is generally used as a purge gas, there is an advantage in that nitrogen doping is realized without installing an additional gas supply line.

On the other hand, when the nitrogen gas flow rate increases to about 4000 sccm, there is a problem in that productivity is deteriorated because the deposition rate is excessively reduced. Therefore, the flow rate of the nitrogen gas should be determined appropriately in consideration of the mechanical properties and productivity of the amorphous carbon film to be produced. Thus, about 1500 to 4000 sccm thereof is preferable, and about 2000 to 3000 sccm thereof is more preferable.

In accordance with the present disclosure, a gas containing oxygen, for example, NO, N2O, CO, CO2, O₂, O3, and the like, is not included in the process gas. Wene the gas containing oxygen is used, the effect may be insufficient or plasma instability may occur. For example, when O₂ was supplied at about 100 sccm, there was little change in physical properties of the film compared to when it was not supplied. When O₂ was supplied at a flow rate exceeding about 100 sccm, plasma was unstable.

The carbon precursor together with the carrier gas is supplied into the chamber, and the carrier gas may include argon gas. It is preferred that the carrier gas does not include helium gas. In general, it is known that when the helium gas is used together with argon gas, this contributes to the improvement of the film quality of the amorphous carbon film. However, in the scheme of the present disclosure in which the above-described high nitrogen gas flow rate is applied, it is identified based on a result of the experiment that the amorphous carbon film of the excellent film quality may be deposited without using the helium gas.

Furthermore, the argon gas may be supplied at a flow rate of about 3000 sccm or smaller. It is more preferable that the argon gas is supplied at a flow rate of about 1500 to 2000 sccm. The flow rate of the argon gas is generally in a range of about 2500 to 4000 sccm. However, as a result of applying the high nitrogen gas flow rate as described above in accordance with the present disclosure, even when the argon gas flow rate is about 2000 sccm or smaller, a decrease in the film quality, the deposition rate, and the like may not occur. On the other hand, when the flow rate of the argon gas exceeds about 3000 sccm, a bow value may be excessively increased, such that a subsequent process may not be possible.

The carbon precursor may be a carbon precursor in a gaseous state at room temperature. The carbon precursor in a gaseous state at room temperature does not need to use a separate vaporizer during the process, and is particularly advantageous in terms of forming a hard amorphous carbon film. Specifically, the carbon precursor may be selected from C₂H₂ (boiling point −84° C.), C₂H₄ (boiling point −104° C.), C₂H₆ (boiling point −88.5° C.), C₃H₆ (boiling point-48° C.), and C₃H₈ (boiling point −43° C.). The supply amount of the carbon precursor may be set to vary depending on a thickness of the amorphous carbon film to be deposited, the temperature of the process chamber, and the like. In one example, the carbon precursor may be supplied at a flow rate of, for example, about 300 to 1000 sccm.

In the amorphous carbon film deposition step S140, a high frequency power of about 1500 W or greater may be applied to discharge the process gas.

Alternatively, in the amorphous carbon film deposition step S140, a low frequency power of about 1000 W or lower, more preferably about 100 to 500 W together with a high frequency power of about 1500 W or greater may be applied. In general, when the amorphous carbon film is deposited using the PECVD process, a radio frequency (RF) of 13.56 MHz is used. When the RF power is increased to increase the selectivity, the plasma density in a central region of the substrate (wafer) increases compared to that in the remaining region. As a result, ion flux and energy are concentrated on the central region, and the sheath region is widened. As the ion flux is concentrated on the central region, the edge region has a relatively smaller ion flux, and thus a difference in thin film thickness occurs, thereby reducing uniformity. In this regard, in the PECVD-based amorphous carbon film deposition process using the high frequency power of about 1500 W or greater resulting from the high frequency of 13.56 MHz, when the low frequency power of about 1000 W or lower resulting from the low frequency such as about 430 kHz is applied together, the thickness uniformity of the thin film may be improved, and characteristics such as hardness and modulus of the film may also be improved.

The amorphous carbon film deposition step S140 may be performed at a pressure of about 5 to 9 Torr, and more preferably at a pressure of about 5 to 7 Torr. As the process pressure decreases, the amorphous carbon film having high hardness and modulus can be deposited. As the process pressure increases, the deposition rate increases, while the compressive stress decreases. Therefore, the process pressure may be determined based on process conditions other than the process pressure. Thus, it is preferable to perform the deposition at a pressure of about 5 to 9 Torr.

The amorphous carbon film deposited in the above-mentioned process according to the present disclosure becomes an amorphous carbon film in which nitrogen is doped into the carbon base. The thickness of the amorphous carbon film may be in a range of about 2700 to 3500 Å.

The amorphous carbon film according to the present disclosure may have a hardness of about 5.0 GPa or greater based on Vickers hardness, a modulus of about 36 GPa or greater, and a density of about 1.7 g/cm³ or greater. As a result, the subsequent process may be easily performed without a separate annealing process.

In addition, the amorphous carbon film according to the present disclosure may receive the compressive stress of about 220 MPa or lower and may exhibit a bow value of about 300 μm or smaller. The compressive stress and the bow value are not excessive, such that a subsequent process to the deposition of the amorphous carbon film may be facilitated.

According to the method for depositing the amorphous carbon film according to the present disclosure, the amorphous carbon film having excellent hardness, modulus, density, and the like and having non-excessive compressive stress and bow value can be deposited via the nitrogen gas (N₂) flow rate control for doping the nitrogen (N), the carrier gas control, the RF power control, and the like while using the low temperature PECVD process of about 400° C.

Accordingly, the deposited nitrogen-doped amorphous carbon layer may have excellent film quality. Thus, for example, even when the number of layers of the NAND flash memory device increases, the deposited nitrogen-doped amorphous carbon layer may be used as a hard mask without significantly increasing the thickness of the amorphous carbon layer.

### EXAMPLES

Hereinafter, a configuration and an effect of the present disclosure will be described in more detail through preferred Examples of the present disclosure. However, this is presented as a preferred implementation of the present disclosure and cannot be interpreted as limiting the present disclosure in any sense.

The contents not described herein may be sufficiently technically inferred by those skilled in this technical field, and thus the description thereof will be omitted.

Table 1 shows the characteristics of the deposited amorphous carbon film under various process conditions.

TABLE 1

| | | Examples | | | | |
|---|---|---|---|---|---|---|
| | | Reference | Comparative | Comparative | Present | Present |
| | | Example 1 | Example 1 | Example 2 | Example 1 | Example 2 |
| Process | HF/LF [W] | 2500 | 2300 | 2300/0 | 2000/0 | 1800/500 |
| conditions | Pressure [Torr] | 8 | 8 | 8 | 7 | 5.5 |
| | Ar [sccm] | 1400 | 3000 | 3000 | 3000 | 1600 |
| | He [sccm] | 500 | 500 | 500 | 0 | 0 |
| | N2 [sccm] | 0 | 0 | 500 | 2000 | 2500 |
| | C₃H₆ [sccm] | 900 | 500 | 500 | 400 | 400 |
| Physical | Thickness[Å] | 19775 | 1018 | 31454 | 28970 | 24118 |
| properties | Thickness | 4.08 | 8.4 | 4.1 | 3.9 | 2.92 |
| measurement | Uniformity (%) | | | | | |
| | K | 0.5442 | 0.249 | 0.0428 | 0.1146 | 0.2780 |
| | K Uniformity (%) | 3.46 | 17.3 | 5.15 | 6.63 | 18.4 |
| | Stress [Mpa] | 50 | −98 | −69 | −73 | −212.6 |
| | Bow value [μm] | 100 | −173 | −137 | −132 | −295 |
| | Hardness [Gpa] | 4.4 | 4.489 | 4.716 | 5.59 | 7.954 |
| | Modulus [Gpa] | 36.6 | 31.59 | 30.806 | 36.5 | 52.136 |
| | Density [g/cm³] | 1.7 | 1.373 | 1.633 | 1.79 | 1.86 |

In Reference Example 1, Comparative Examples 1 to 2, and Present Examples 1 to 2, a spacing between the substrate and the showerhead was 300 mils.

In Reference Example 1, amorphous carbon film deposition was performed at about 610° C. as a high temperature, and in Comparative Examples 1 to 2 and Present Example 1 to 2, amorphous carbon film deposition was performed at about 400° C. as a relatively low temperature.

In the Table 1, HF denotes high frequency power (W), and LF denotes low frequency power (W).

In addition, in the Table 1, the thickness and K (extinction coefficient) mean the average thickness and the average K value at 49 positions of the wafer. In Table 1, the uniformity (%) was calculated as {(maximum-minimum value)/(2*average value)}*100.

In the Table 1, in the stress and the bow value, “−” means that the film is subjected to the compressive stress, and “+” means that the film is subjected to the tensile stress.

Referring to the Table 1, in the case of Comparative Example 1 in which the process gas did not include nitrogen gas and Comparative Example 2 in which the process gas included nitrogen gas but the nitrogen gas flow rate was only 500 sccm, the thickness uniformity was relatively poor, the hardness was lower than 5.0 GPa, the modulus was lower than 36 GPa, and the density was also lower than 1.7 g/cm³.

On the other hand, in Present Examples 1 and 2 in which the nitrogen gas was included in the process gas, and the flow rate thereof was 1500 sccm or greater, the hardness of 5.0 GPa or greater, the modulus of 36 GPa or greater, and the density of 1.7 g/cm³ or greater together with good thickness uniformity were exhibited. Although in Present Examples 1 to 2 the deposition was performed at a low temperature, the physical properties of the amorphous carbon film were equal to or greater than the physical properties of the amorphous carbon film deposited in the method according to Reference Example 1 in which the deposition was performed at a high temperature. In addition, in the case of Present Examples 1 to 2, the film is subjected to the compressive stress of 220 MPa or lower, and a bow value of 300 μm or smaller is exhibited. Thus, it may be identified that the amorphous carbon film as deposited according to each of Present Examples 1 to 2 is not subjected to an excessive compressive stress (e.g., 400 MPa).

In addition, it was identified based on a comparing result between Present Example 1 and Present Example 2 that Present Example 2 in which the low frequency power together with the high frequency power is applied exhibited better results in terms of the thickness uniformity, hardness, modulus, density, and the like than those in Present Example 1 in which only the high frequency power is applied.

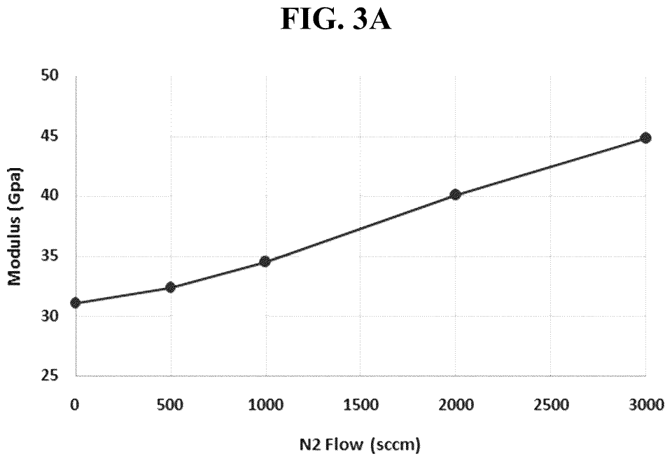

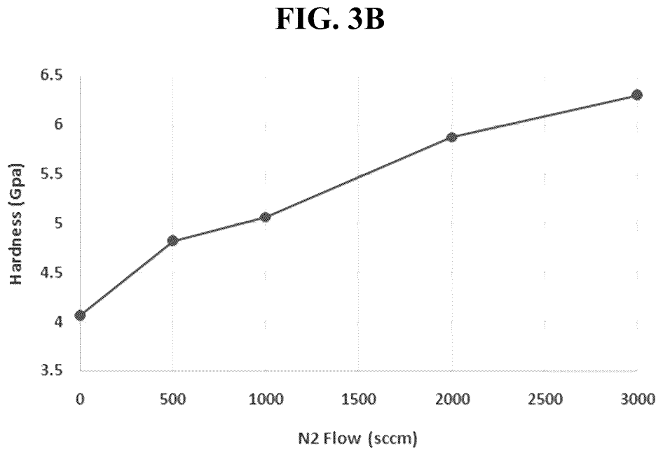

FIGS. 3A and 3B show changes in modulus and hardness based on the nitrogen gas flow rate.

The nitrogen gas flow rate was changed to each of 0 sccm, 500 sccm, 1000 sccm, 2000 sccm, 3000 sccm. The same process conditions as those in Present Example 1 were applied except for the nitrogen gas flow rate.

Referring to FIGS. 3A and 3B, it may be identified that each of the modulus and the hardness of the deposited amorphous carbon film tends to increase as the nitrogen gas flow rate increases. It may be identified that when the nitrogen gas flow rate is 1500 sccm or greater, the hardness of 5.0 GPa or greater and the modulus of 36 GPa or greater are simultaneously exhibited.

As seen from the results of Table 1 and FIGS. 3A and 3B, it may be identified that in the method for depositing the amorphous carbon film according to the present disclosure, applying the low frequency power together with the high frequency power is more advantageous in terms of improving the modulus and hardness of the amorphous carbon film, compared to applying only the high frequency power.

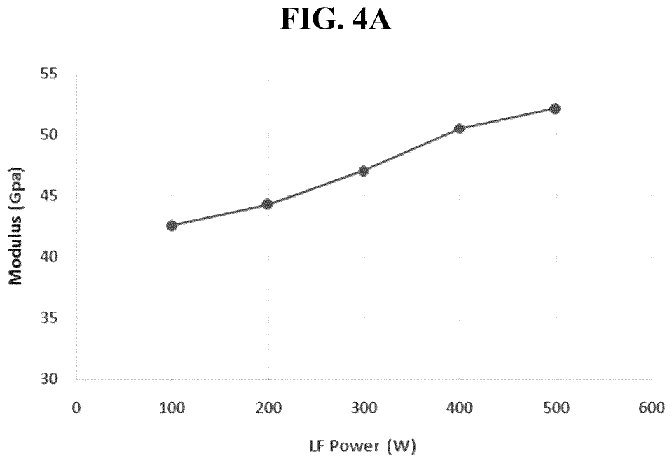

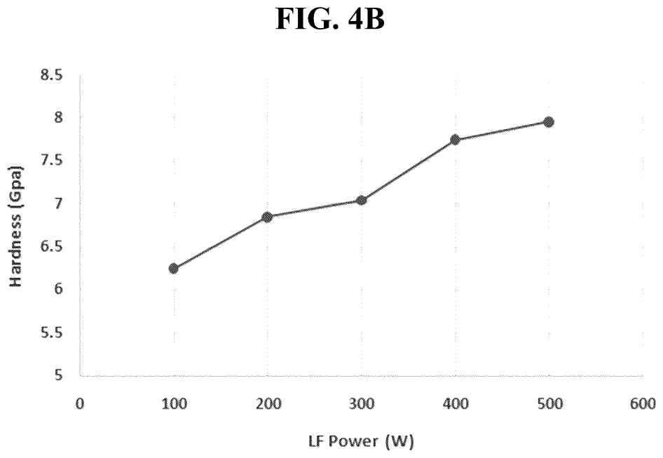

FIG. 4A and FIG. 4B show changes in the modulus and the hardness based on the low frequency power. The high-frequency power was 1800 W, and other process conditions were the same as those in Present Example 2.

Referring to FIGS. 4A and 4B, it may be identified that as the low frequency power applied together with the high frequency power increases, each of the modulus and the hardness of the deposited amorphous carbon film tends to increase. When the 500 W low frequency power is added, both the hardness and the modulus are significantly improved.

Although the present disclosure has been described with reference to the accompanying drawings, the present disclosure is not limited by the embodiments disclosed herein and the drawings, and it is obvious that various modifications may be made by those skilled in the art within the scope of the technical idea of the present disclosure. In addition, although the effects based on the configuration of the present disclosure are not explicitly described and illustrated in the description of the embodiment of the present disclosure above, it is obvious that predictable effects from the configuration should also be recognized.

1. A method for depositing an amorphous carbon film, the method comprising:
(a) loading a substrate into a chamber;
(b) supplying a carbon precursor and a nitrogen gas into the chamber;
(c) raising a temperature of the substrate to 350 to 450° C.; and
(d) discharging the carbon precursor and the nitrogen gas in the chamber to deposit a nitrogen-doped amorphous carbon film on the substrate,
wherein a flow rate of the nitrogen gas is in a range of about 1500 to 4000 sccm during the step (d).

2. The method for depositing the amorphous carbon film of claim 1, wherein the carbon precursor together with a carrier gas is supplied into the chamber, wherein the carrier gas includes argon gas.

3. The method for depositing the amorphous carbon film of claim 2, wherein the carrier gas is free of helium gas.

4. The method for depositing the amorphous carbon film of claim 2, wherein the argon gas is supplied at a flow rate of about 3000 sccm or smaller.

5. The method for depositing the amorphous carbon film of claim 1, wherein the carbon precursor is a carbon precursor in a gaseous state at room temperature.

6. The method for depositing the amorphous carbon film of claim 5, wherein the carbon precursor is selected from C₂H₂, C₂H₄, C₂H₆, C₃H₆ and C₃H₈.

7. The method for depositing the amorphous carbon film of claim 1, wherein in the step (d), a high frequency power of about 1500 W or greater is applied.

8. The method for depositing the amorphous carbon film of claim 1, wherein in the step (d), both a high frequency power of about 1500 W or greater and a low frequency power of about 1000 W or lower are applied.

9. The method for depositing the amorphous carbon film of claim 1, wherein the step (d) is performed at a pressure of about 5 to 9 Torr.
